(19) United States
(12) Patent Application Publication
(10) Pub. No.: US 2019/0145621 A1
(43) Pub. Date: May 16, 2019

(54) ELECTRICITY GENERATION DEVICE WITH A THERMOELECTRIC GENERATOR AND CONTAINER OF COMPRESSED FLUID

(71) Applicant: SPENCER ADAM TURNER, BRANSGORE (GB)

(72) Inventor: SPENCER ADAM TURNER, BRANSGORE (GB)

(21) Appl. No.: 15/521,129

(22) PCT Filed: Oct. 26, 2015
(86) PCT No.: PCT/GB2015/053211

§ 371 Date: Apr. 21, 2017

(30) Foreign Application Priority Data
Oct. 24, 2014 (GB) 1418999.7

(51) Int. Cl. F23D 14/28; F24C 3/14; H01L 35/30

(52) U.S. Cl. CPC F23D 14/28; F23M 2900/13003; H01L 35/30; F24C 3/14

(57) ABSTRACT

An electricity generation device comprising a thermoelectric generator and a container of compressed fluid, in which said thermoelectric generator comprises a hot surface and a cold surface, in which said container comprises an exterior surface and an aperture, in which said device comprises a release valve for opening said aperture to release said compressed fluid, in which expansion of said compressed fluid cools said exterior surface, and in which a heat sink extends from said cold surface to at least part of said exterior surface.

The present invention relates to an electricity generation device which uses a thermoelectric generator (TEG) and a container of compressed fluid, which is for use particularly, but not exclusively, as a portable camping stove.

Portable gas powered camping stoves suffer from a number of problems. Firstly, of the two gases which are commonly used as fuel, neither is ideal. Both butane and propane have their advantages, but they both have drawbacks. Butane is the most suitable because it is less volatile than propane, because at room temperature it produces 2 bar of pressure, whereas propane produces 5 bar. As such, butane can legally be used and stored indoors, while propane cannot, and in addition propane canisters need to be stronger and heavier to hold the additional pressure. Further, butane contains about 12 percent more energy per litre than propane. However, because its boiling point is only −2 degrees centigrade butane's performance as a gas fuel falters at lower ambient temperatures because it fails to atomise efficiently. When compressed butane expands it cools the canister to below ambient temperature quickly, and can reach freezing or below in a short time. Therefore, it cannot be used effectively at anything below 5-10 degrees centigrade, and certainly not at or below freezing. Propane on the other hand can be used at lower temperatures because its boiling point is −42 degrees centigrade.

Secondly, the burning heads of known camping stoves are inefficient because a proportion of the heat generated radiates laterally away from the item to be heated above. Gas flames radiate heat in all directions, so while heat radiating upwards will be utilised, the heat which is radiated elsewhere is wasted.

Finally, when compressed butane or propane expands it cools. This is effectively a refrigeration benefit resulting from the energy imparted to the gas when it was compressed. However, in known portable camping stove arrangements this cooling effect is wasted as it is not put to any work.

An entirely different problem can be encountered when outdoors and away from a ready source of electrical power. Portable electronic devices such as mobile phones, tablets, radios, GPS devices and so on are usually powered by rechargeable batteries. As such, they have a limited life before they require recharging. To address this problem it is known to provide portable external battery packs to provide additional charge, however once used these must also be recharged.

It is also known to provide portable devices which can generate an electrical charge from an available source of energy such as human power or the heat of a camping stove. However, to date such devices are basic and do not provide a particularly useful source of electrical power. In terms of utilising the heat of a camping stove, it is known to mount a basic TEG over the flame. However, the temperature differential between the flame and the ambient temperature is relatively small, resulting in a low level of performance. In addition, this kind of arrangement provides a constantly varying output, which is not ideal.

The present invention is intended to overcome some of the above described problems.

Therefore, according to the present invention, an electricity generation device comprises a thermoelectric generator and a container of compressed fluid, in which said thermoelectric generator comprises a hot surface and a cold surface, in which said container comprises an exterior surface and an aperture, in which said device comprises a release valve for opening said aperture to release said compressed fluid, in which expansion of said compressed fluid cools said exterior surface, and in which a heat sink extends from said cold surface to at least part of said exterior surface.

Thus, the present invention addresses the two main problems discussed above at the same time. With this arrangement heat from the TEG is directed to the surface of the container of compressed fluid, which can prevent the contents of the container from getting too cold. As referred to above, this is an issue with butane, so if a canister of butane is prevented from falling below about 10 degrees centigrade by being thermally coupled to the heat sink of a TEG, it could be used in far lower ambient temperatures than currently.

Secondly, the cooling effect generated by releasing the compressed fluid from the container is used to cool the cold surface of the TEG. This results in greater TEG efficiency because the temperature differential is greater than it otherwise would be. In addition, the cooling effect generated by releasing a compressed fluid from a container is utilised to assist in the generation of electricity, rather than simply being wasted.

It will be appreciated that the invention can be used with any kind of TEG, and with any kind of container of compressed fluid. As such, it can find application in any industrial or commercial setting where a TEG may be used to generate electricity. It would simply be necessary to provide a container of compressed fluid and to thermally couple it's exterior surface to the heat sink of the TEG. The invention can also be used in any such setting where compressed fluids are released from containers and a cooling effect is experienced. It would simply be necessary to provide a TEG, and to thermally couple the heat sink thereof to the exterior surface of the container.

The container in the present invention can be a canister or cylinder in which the compressed fluid is stored, but it can also comprise pipework leading therefrom. This is because in an industrial setting the thermal reaction caused by atomisation of the compressed fluid can sometimes occur downstream of the storage tank. Therefore, the container can be the containment structure as a whole in which the compressed fluid is not only stored, but also where the thermal reaction caused by atomisation occurs. What is essential is that the exterior surface feature is in the area where this thermal reaction happens. In a canister of butane for a camping stove that thermal reaction occurs in the canister itself, but in an industrial setting this thermal reaction can occur in pipework leading away from the container.

In a preferred embodiment the device can further comprises a burner, the release valve can be fluidly connected to the burner, and the compressed fluid can be combustible and when expanded comprise a fuel for the burner. Combustion of the expanded fluid can heat the burner, and a thermal conductor can extend from the burner to the hot surface.

With these additional features the performance of the invention can be significantly improved. Firstly, some of the heat generated by the burning of the butane gas is directed via the TEG to the container, which can be used to prevent the contents of the container from getting too cold. Secondly, this heat is used to create a large temperature differential in the TEG, resulting in greater TEG efficiency. Finally, this arrangement provides the TEG with a constant heat from the thermal conductor, which does not vary like that directly over a burning flame. As such the output of the TEG is much more stable than in known arrangements.

It will be appreciated that the invention involves utilising the cooling effect of releasing a compressed fluid and the waste heat of a burning the then expanded fluid to simultaneously create a beneficial temperature differential in a TEG, and prevent the container from dropping below a particular temperature. In order to best achieve these advantages it is necessary to balance the thermal conduction characteristics of the various structures of the device as required. For example, the heat sink can be sized and configured so that in an ambient temperature of 20 degrees centigrade it keeps the container at more than 10 degrees centigrade when the waste heat heats the thermal conductor to 400 degrees centigrade. Likewise, the burner can be configured to generate this level temperature for the thermal conductor in normal use, and the TEG can be scaled accordingly. However, it will be appreciated that in uncontrolled environments such as are experienced outdoors, the ambient air temperature and atmospheric conditions are significant variables which would affect this desired range of performance.

Therefore, in one embodiment of the invention an air gap can be provided between a section of the heat sink and at least part of the exterior surface of the container, and a fan can then be disposed in the air gap, which can be operable in a first direction to radiate heat from the heat sink to the container, and in a second direction to radiate heat from the container to the heat sink.

The fan can therefore be used to regulate the temperatures in the device if they drop below, or rise above, what is desired for optimum efficiency. In particular, if the fan is used to regulate the temperature of the container, then if the container gets too cold more heat can be radiated to it through the air from an area of the heat sink which is hotter than that adjacent to the container. Conversely, if the container gets too hot, then cold air from atmosphere can be drawn over it by running the fan in the opposite direction. Alternatively, it is also possible for the fan to be used to regulate the temperature of the TEG. If so, then if the TEG is too hot the effectiveness of the heat sink can be improved by operating the fan in the first direction to radiate heat away.

In order to achieve these functions the device can further comprise a thermometer to detect the temperature of the container and a control means operatively connected to the fan. The control means can then operate the fan in the first direction when the thermometer detects a temperature of the container below a first pre-determined threshold, and in the second direction when the thermometer detects a temperature of the container above a second pre-determined threshold.

It will be appreciated that the first and second pre-determined thresholds will be a matter for the skilled person to determine, according to the particular size and configuration of the various components of the device. As outlined above, the invention finds particular application in a butane power camping stove, in which the canister of butane is prevented from dropping below a temperature at which the compressed butane fails to atomise into a gas, and is prevented from rising above a temperature at which the canister may become dangerously hot. If so, the first pre-determined threshold can be somewhere between 5 and 10 degrees centigrade, and the second pre-determined threshold can be somewhere between 30 and 40 degrees centigrade. The control means can be arranged to operate the fan continuously once it has begun, or it can be arranged to operate the fan in each direction until the thermometer detects that the container has achieved a temperature within a pre-determined safe range, for example between 15 and 25 degrees.

In order to improve the efficiency of the device the burner can be adapted to absorb more heat than in conventional arrangements, and in particular the heat which is usually radiated laterally or downwardly and wasted.

Therefore, in a preferred construction the burner can comprise an heating axis and can radiate heat in use in a first direction along the heating axis. The burner can also comprise an annular body comprising an outer ring of gas outlets and an inner ring of gas outlets disposed radially inside the outer ring. Further, the inner ring can be axially positioned below the outer ring on the heating axis. With this arrangement heat radiated laterally from the inner ring is captured, and is absorbed by the burner.

In addition, the annular body of the burner can comprise a first annular trough at a base of which the outer ring can be disposed, and a second annular trough at a base of which the inner ring can be disposed. This construction ensures that heat radiated laterally from the lower section of the burning gas flames is also captured, and absorbed by the burner.

The burner, the thermal conductor, the TEG, the heat sink and the container can be arranged in any physical positions in relation to one another, provided the thermal relationships between them are as referred to above. However, in a preferred construction the release valve can be fluidly connected to the burner by a fluid pipe, and the thermal conductor can comprise a tubular part which defines the fluid pipe, and a planar part extending from the tubular part which contacts said hot surface.

The heat sink can comprise a primary heat sink structure in thermal connection with the cold surface and comprising a plurality of cooling fins. Further, the fluid pipe can comprise an axis; the primary heat sink structure can be annular, and the plurality of cooling fins can extend radially outwardly from the axis. The primary heat sink structure can also comprise an underside, and the heat sink as a whole can further comprises a tubular housing which surrounds at least part of the container, with a first end thereof comprising a radially extending flange in thermal connection with the underside of the primary heat sink structure. With this arrangement of parts the device has a compact and integrated structure which is easy to handle and to transport. This is of particular benefit when the invention is embodied as a camping stove.

The air gap mentioned above can extend between the underside of the primary heat sink structure and a top side of the container, and the fan can be mounted to the underside in a position which is axially aligned with the TEG. This configuration allows for the fan to achieve an effective performance, and it is also a neat and compact arrangement.

An air passageway can be provided between the container and the tubular housing, through which the fan can draw air when it is operated in the second direction. It will be appreciated that with such a construction the heat sink between the cold surface of the TEG and the container will to some extent comprise not a direct connection between physical parts, but an air gap through which heat can radiate, or the cooling effect of the release of the compressed fluid can be transferred. Again, the impact of this can be factored into the design parameters of the device and its various components so it will still thermally function as set out above. It may be desired to make this air gap as minimal as possible to maximise the area of a direct connection between the container and the tubular housing.

As explained above the invention finds particular application as a camping stove, so therefore in one version the device can be a portable stove comprising a central body for retaining the container, a burner for burning the expanded fluid from the container, a platform above the burner for supporting an item to be heated, and a manually operable control knob for opening and closing the release valve.

Further, the central body can comprise a plurality of legs on which the portable stove can be standable in use. Each of the plurality of legs can be mounted to the central body by a first hinge, and can be moveable between a collapsed position in which it overlies the central body and an unfurled position in which it extends away from the body at an angle. This legs arrangement provides a beneficially compact arrangement for when the portable stove is stored or transported, and a robust and secure arrangement for when the portable stove is to be used.

Preferably a ring can be mounted to an exterior side of the central body, and can be axially movable along the central body. Each of the plurality of legs can then be connected in the same manner to the ring by a support strut, which can be mounted at an inner end thereof to a second hinge on the ring and at an outer end to a third hinge on the leg. As such the rotational position of each of the plurality of legs on its first hinge is the same as the others. This structure ensures that the legs assume the same position at all times, and therefore can form a stable support structure. It also means all the legs can be opened out by moving just one of them.

It will be appreciated that electricity generated by the TEG in use can be put to any purpose. However, in a preferred construction the device can further comprise a rechargeable battery for storing electrical charge generated by the TEG in use. The rechargeable battery can be any of the known constructions which is capable of storing a charge, but also of delivering a charge via a universal outlet such as a USB port. As such, when the TEG is operating in use the electrical charge it generates can be directed via the battery directly to a portable device to be charged, or it can be stored by the battery for future use.

Preferably the rechargeable battery can be mounted on one of the plurality of legs. With this arrangement the battery is easily accessible in use. Further, the power outlet can be adjacent to an outer end of the leg, so it is spaced from the burner, which improves safety.

It will be appreciated that if the container is disposed inside the central body/tubular housing as described above, there will need to be a mechanism to retain the top side of the container therein. Therefore, in one version of the invention the container can comprise a retention collar, and the device can comprise a releasable mounting for retaining the container in the central body. The releasable mounting can comprise a plurality of lock arms, each of which can be movable between a lock position in which it retains the retention collar, and a release position in which it allows movement of the retention collar in and out of the releasable mounting. Each of the plurality of lock arms can be biased into its lock position by a first spring, and the container can be biased away from the releasable mounting by a second spring.

With this construction the container can be pushed into the central body against the force of the second spring, until the retention collar engages with the lock arms and they retain it in place. The force of the second spring then acts to bias the retention collar into engagement with the lock arms to ensure a stable engagement is provided.

It will be appreciated that containers of compressed fluid like butane can be dangerous if they are over heated. The fluid can expand, and eventually force the container to explode. It is known to provide butane canisters with an expanding neck section which expands if the pressure inside the canister reaches a dangerous level. This serves as an indicator to the user that the canister is too hot, and that it needs to be moved to a cooler place. If the present invention operates correctly then the temperature of the container should not rise to a dangerous level, but it is desired to provide a novel safety feature to prevent any such rise in temperature from becoming a danger.

Therefore, the device can comprise a fluid inlet passageway to which the container is fluidly connected, and the fluid inlet passageway can comprises a pressure valve. A linkage can connect the pressure valve to the plurality of lock arms, and the pressure valve can be movable between a first position in which the linkage allows the plurality of lock arms to assume the lock position, and a second position in which the linkage moves the lock arms into the release position. The pressure valve can be biased into the first position by a third spring, and it can be configured to move into the second position when a pre-determined back pressure is present in the fluid inlet passageway. The third spring can be a spring which is solely provided for this purpose, but in one embodiment its function can be provided by the second spring referred to above.

If the container of compressed fluid overheats the pressure inside increases. This increase in pressure forces the fluid from the container, into the fluid inlet passageway and on into the fluid pipe up to the burner. This in turn results in an even greater pressure building up in the fluid inlet passageway and the fluid pipe, which will eventually reach the level of the pre-determined back pressure. When this happens the pressure valve moves into its second position, which moves the lock arms into the release position. The container is then ejected from the central body by the force of the second spring acting against it. Therefore, if the temperature of the container reaches a dangerous level, it will be automatically ejected from the device. This will interrupt the burning process, and the source of heat will cease.

Preferably, a plane of the outer ends of the plurality of legs when in the unfurled position can be spaced from a plane of a bottom of the container, such that a gap is provided under the container when the portable stove stands in use. This arrangement means that if the container is ejected as described above, there is space for it to move downwards. Were this not the case and the container rested on the ground, the device may be forced upwards by the second spring should the pressure valve move into its section position in use.

During further development of the above described invention a number of improvements were discovered. These are vested in the second embodiment of the present invention described below. However, in short the key differences are as follows.

Firstly, an air gap can be provided between a section of the heat sink and at least part of the exterior surface, the device can further comprise a fan disposed in the air gap, and the fan can be operable to radiate heat from said heat sink to said container. This fan can be operated continuously in this way when the release vale is open. The advantages of this are explained below.

Further a selectively open and closable grill comprising a plurality of open and closable apertures can be provided between the section of the heat sink and the part of the exterior surface, which grill can be movable between a first position in which the apertures are open, a second position in which the apertures are partially open, and a third position in which the apertures are closed. Again, the advantages of this are explained below.

In this second embodiment the device can also be a portable stove comprising a central body for retaining the container, a burner for burning the expanded fluid from the container, a platform above the burner for supporting an item to be heated, and a manually operable control knob for opening and closing the release valve. However, in the vicinity of the container the central body can comprise a plurality of first circumferential sections which can be a first radius from a central axis of the portable stove, and a plurality of second circumferential sections which can be a greater second radius from said central axis.

The device further can further comprise a burner, the release valve can be fluidly connected to the burner, and the compressed fluid can be combustible and when expanded can comprise a fuel for the burner. Combustion of the expanded fluid can heat the burner, and a thermal conductor can extend from a point above said burner to said hot surface. Once again, the advantages of this slightly different arrangement are described in full below.

The present invention can be performed in various way, but two embodiments will now be described by way of example, and with reference to the accompany drawings, in which:

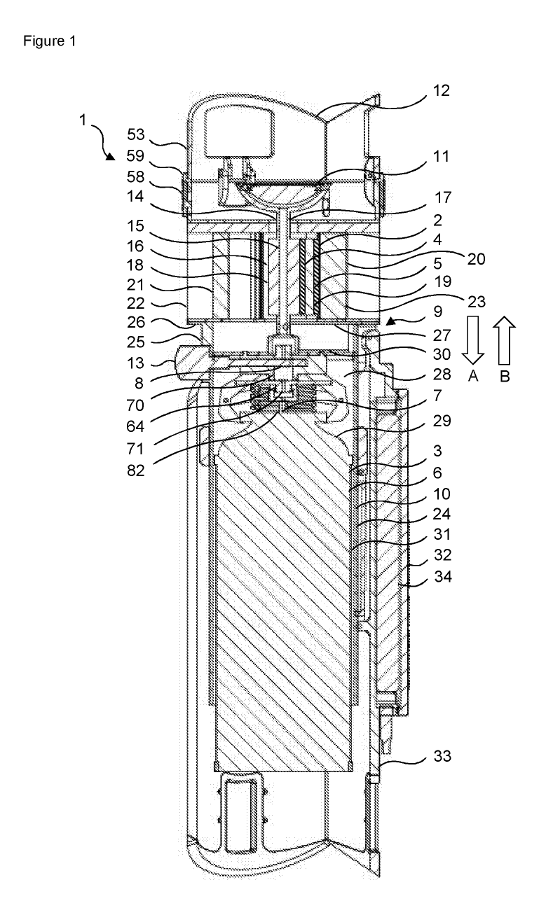

FIG. 1 is a cross-sectional side view of an electricity generation device according to the present invention:

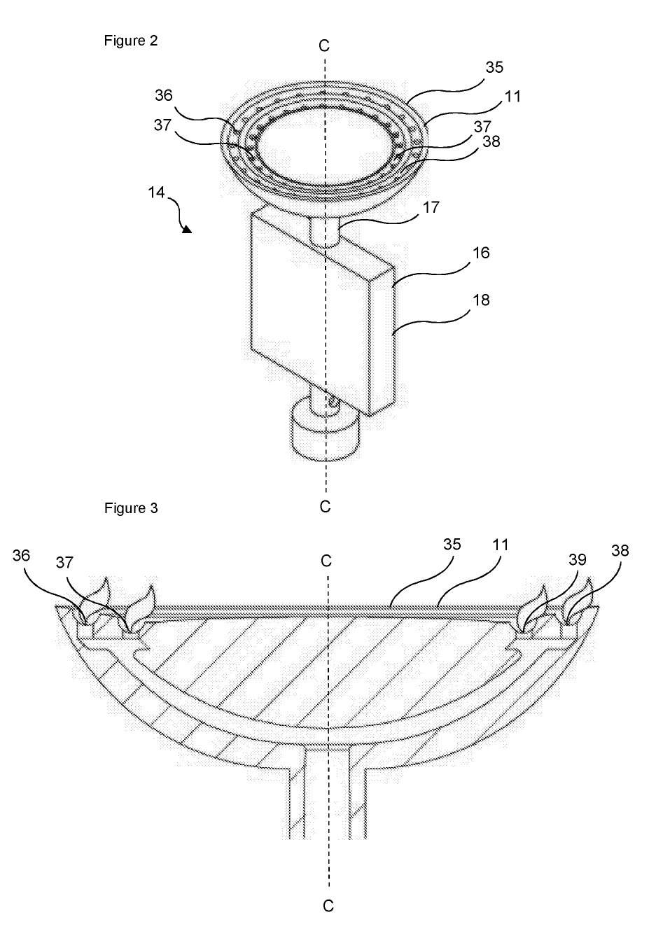

FIG. 2 is a perspective view of a burner component of the electricity generation device as shown in FIG. 1;

FIG. 3 is a cross-sectional side view of a section of the burner component as shown in FIG. 2;

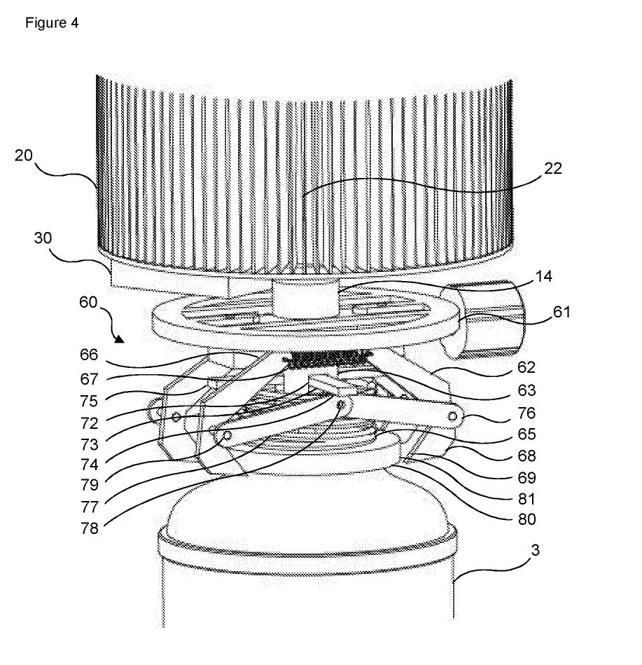

FIG. 4 is a perspective view of an internal section of the electricity generation device as shown in FIG. 1;

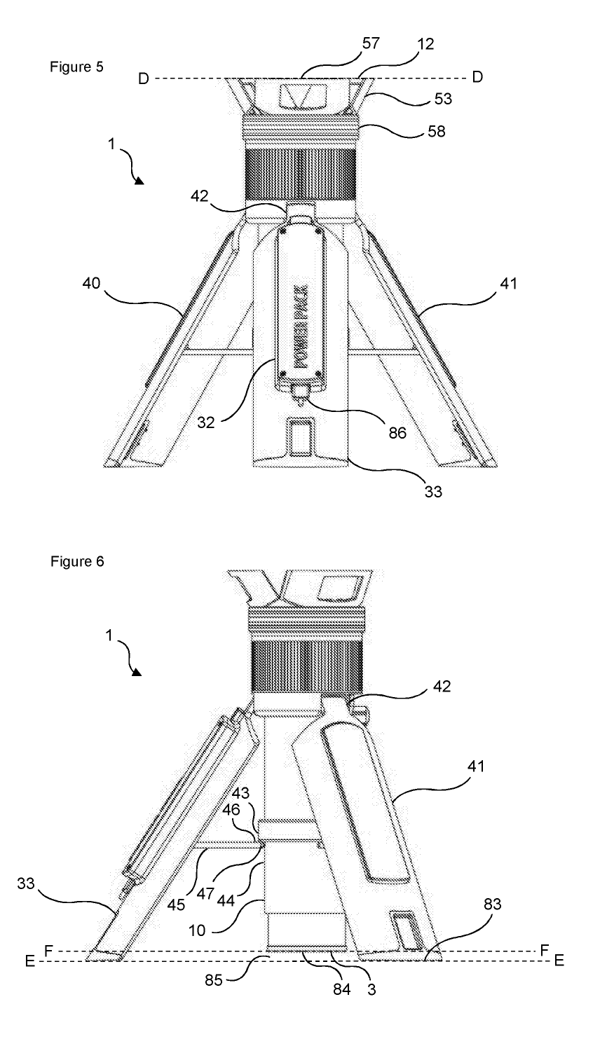

FIG. 5 is a side view of the electricity generation device as shown in FIG. 1 in an unfurled position;

FIG. 6 is a side view of the electricity generation device as shown in FIG. 1 in an unfurled position;

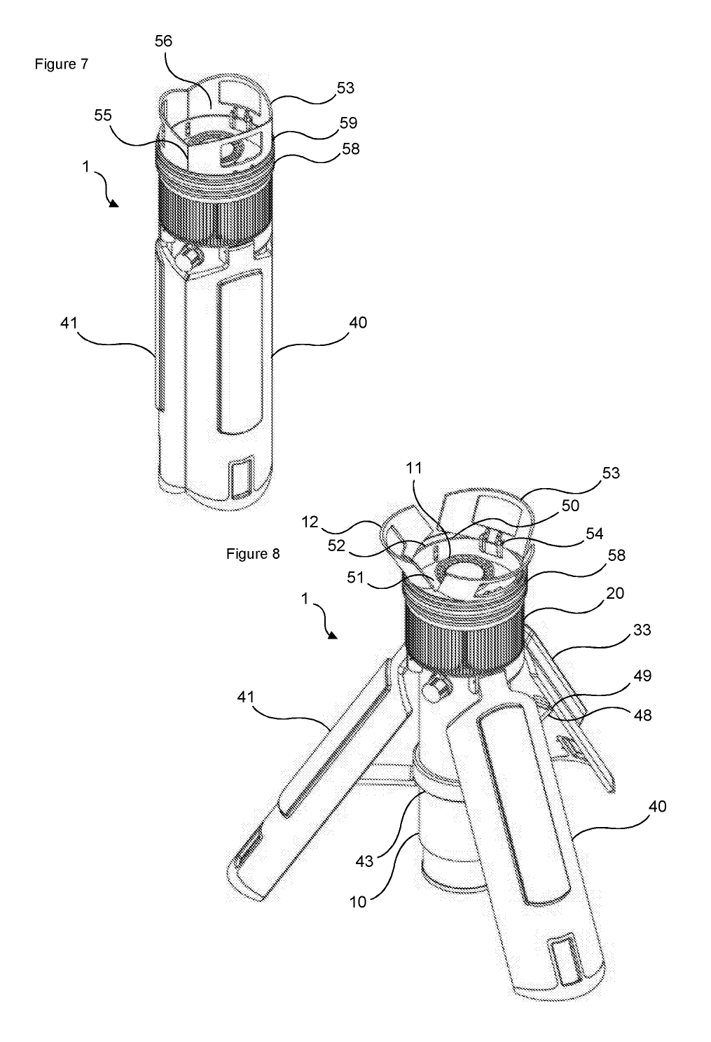

FIG. 7 is a perspective view of the electricity generation device as shown in FIG. 1 in a collapsed position;

FIG. 8 is a perspective view of the electricity generation device as shown in FIG. 1 in an unfurled position;

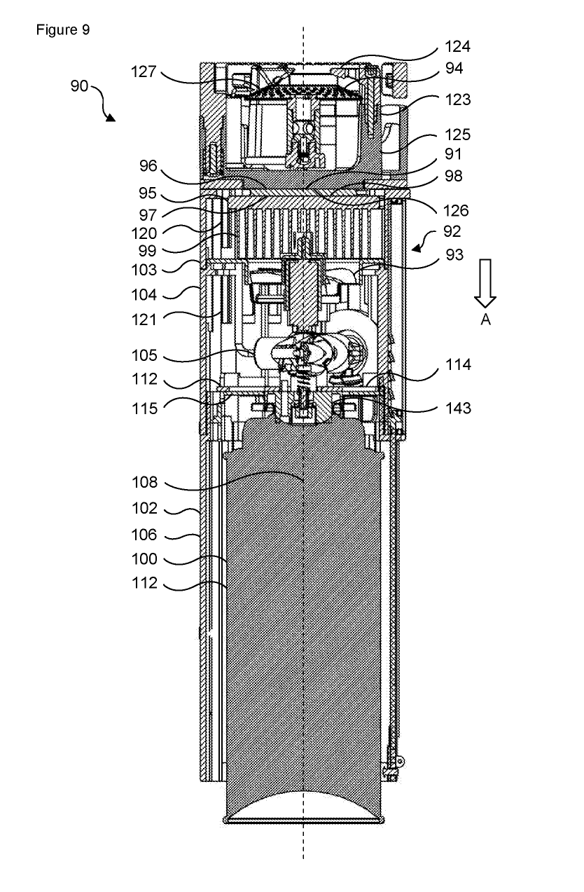

FIG. 9 is a cross-sectional side view of a second electricity generation device according to the present invention;

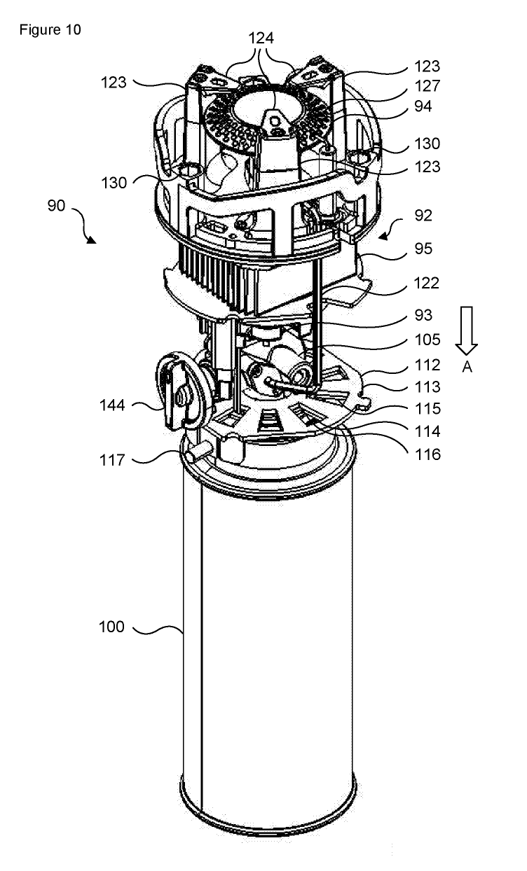

FIG. 10 is a perspective view of the internal components of the second electricity generation device as shown in FIG. 9;

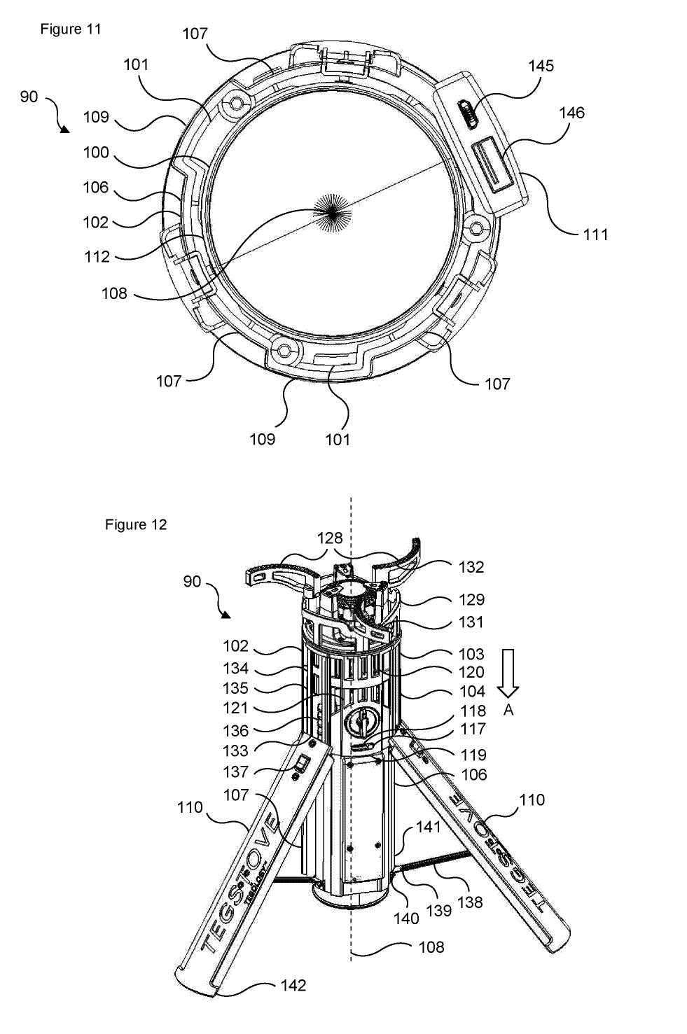

FIG. 11 is an underside view of the second electricity generation device as shown in FIG. 9; and

FIG. 12 is a perspective view of the second electricity generation device as shown in FIG. 9.

As shown in FIG. 1, an electricity generation device, in the form of portable camping stove 1, comprises a TEG 2 and a container of compressed fluid, in the form of canister of butane 3. The TEG 2 comprises a hot surface 4 and a cold surface 5, and the container (3) comprises an exterior surface 6 and an aperture 7. The device (1) comprises a release valve 8 for opening the aperture 7 to release the butane, and as explained further below expansion of the butane cools the exterior surface 6. A heat sink, generally designated 9, extends from the cold surface 5 to at least part of the exterior surface 6.

The camping stove 1 is a portable device comprising a central body 10 for retaining the butane canister 3, a burner 11 for burning the butane, a platform 12 above the burner 11 for supporting an item to be heated (not shown), and a manually operable control knob 13 for opening and closing the release valve 8. The release valve 8 is a rotatable linear valve which can be positioned anywhere between a closed position and a fully open position, in order to control the amount of butane provided to the burner 11.

The release valve 8 is fluidly connected to a burner component 14, which is shown in isolation in FIG. 2. This single item defines the burner 11, a fluid pipe 15 which leads from the release valve 8 to the burner 11 (as shown in FIG. 1), and a thermal conductor 16, which is formed by the physical structure itself below the burner 11. The thermal conductor 16 comprises a tubular part part 17 which defines the fluid pipe 15, and a planar part 18 extending from the tubular part 17. The planar part 18 corresponds in size and shape to the hot surface 4 of the TEG 2, and it is in direct contact with it, as illustrated in FIG. 1.

The TEG 2 is a known device and it comprises the traditional structure of the hot surface 4 which is formed from a known kind of substrate, a bank of P and N type semiconductors 19, and the cold surface 5, which is also formed from a known kind of substrate. The manner in which a TEG of this kind operates is well known, and as such it's structure and workings will not be further described here.

On the cold side of TEG 2 is the heat sink 9. This comprises a primary heat sink structure 20, which is an annular body 21 with a plurality of radially extending cooling fins 22 (best seen in FIG. 4). In direct contact with the cold surface 5 of the TEG 2 is a planar part 23, which is visible in cross section in FIG. 1. Therefore the cold surface 5 of the TEG 2 is in continuous direct contact with primary heat sink structure 20. As such, the heat passed through the TEG 2 is primarily dissipated to atmosphere via the planar part 23 and the cooling fins 22 extending from it. However, the heat sink 9 also comprises tubular housing 24 which surrounds the butane canister 3. The tubular housing 24 is the same component as the central body 10. A first end 25 of the tubular housing 24 comprises a radially extending flange 26 which is connected to an underside 27 of the primary heat sink structure 20. Therefore, heat passed through the TEG 2 is also directed to the tubular housing 24, where it is balanced by the cooling effect generated by the butane canister 3 when the butane is released in use.

An air gap 28 extends between the underside 27 of the primary heat sink structure 20 and a top side 29 of the butane canister 3, and an electric fan 30 is mounted to the underside 27 in a position which is axially aligned with the TEG 2. The fan 30 is operable in a first direction, as indicated by arrow A, to radiate heat from the primary heat sink structure 20 to the butane canister 3, and in a second direction, as indicated by arrow B, to radiate heat from the butane container 3 to the primary heat sink structure 20.

An air passageway 31 is provided between the butane canister 3 and the tubular housing 24, through which the fan 30 can draw air when it is operated in the second direction. The air passageway 31 is facilitated by the radius of the inside of the tubular housing 24 being greater than the radius of the butane canister 3. The presence of the air passageway 31 means that the heat sink 9 also comprises the space between the tubular housing 24 and the butane canister 3, through which heat can radiate, or the cooling effect of the release of the butane can be transferred.

The fan 30 is controlled by an electronic circuit provided on a PCB (not visible), which is housed in an enclosure 32 provided on leg 33, alongside a rechargeable battery 34. A thermometer (not visible) is provided in the tubular housing 24 to detect the temperature of the butane canister 3, which is connected to the PCB. Using power from the rechargeable battery 34, the electronic circuit operates the fan 30 in the first direction A when the thermometer detects a temperature of the butane canister 3 below a first pre-determined threshold, and in the second direction B when the thermometer detects a temperature of the butane canister 3 above a second pre-determined threshold. In this illustrative example the first pre-determined threshold is 10 degrees centigrade, and the second pre-determined threshold is 35 degrees centigrade, however it will be appreciated that these thresholds can be set to different levels depending on how the skilled person designs and sets-up the system. The priorities for the skilled person will be to ensure that the butane canister 3 remains within a temperature range in which the butane atomises efficiently into a burnable gas, and also to ensure that it does not reach a dangerously high temperature at which it may explode. As the same time, the skilled person will want to ensure that the TEG achieves maximum achievable efficiency by maintaining the greatest temperature differential between the hot surface 4 and the cold surface 5.

In addition, in this illustrative example once the electronic circuit operates the fan 30 in the first direction A, it will operate the fan 30 until the thermometer detects that a temperature of the butane canister 3 is 20 degrees, and once it operates the fan 30 in the second direction B, it will operate it until the thermometer detects that the butane canister 3 is at 25 degrees. Again, it will be appreciated that these temperature cut-offs can be established as required in practice by the skilled person.

Referring to FIG. 2, this illustrates the structure of the burner component 14, and the burner 11 at the top. FIG. 3 shows the burner 11 in cross-section. As shown in these figures, the burner 11 comprises a heating axis C-C and radiates heat in use in a first direction, which is upward in the figures, along the heating axis C-C. The burner 11 comprises an annular body 35 with an outer ring of gas outlets 36 and an inner ring of gas outlets 37 disposed radially inside the outer ring 36. As is clear from the figures, the inner ring 37 is positioned below the outer ring 36 on the heating axis C-C.

In addition, the annular body 35 comprises a first annular trough 38 at a base of which the outer ring 36 is disposed, and a second annular trough 39 at a base of which the inner ring 37 disposed. This arrangement of gas outlets ensures that much of the heat which is not radiated upwards along the axis C-C is directed to the annular body 35 of the burner 11, serving to heat it. That heat is transferred to the planar portion 18 of the burner component 14 where it is provided to the hot surface 4 of the TEG 2.

Referring to FIGS. 5-8, the central body 10 comprises three legs 33, 40 and 41, on which the portable stove 1 is standable. Each of the legs 33, 40 and 41 is mounted to the central body 10 by a first hinge 42, and is moveable between a collapsed position as shown in FIGS. 1 and 7 in which it overlies the central body 10, and an unfurled position as shown in FIGS. 5, 6 and 8 in which it extends away from the central body 10 at an angle.

A ring 43 is mounted to an exterior side 44 of the central body 10, and is axially movable along the central body 10. Each of the legs, 33, 40 and 41 is connected in the same manner to the ring 43 by a support strut 45, which is mounted at an inner end 46 thereof to a second hinge 47 on the ring 43 and at an outer end 48 to a third hinge 49 (visible in FIG. 8) on the leg 33, 40 and 41. As such the rotational position of each of the legs 33, 40 and 41 on its first hinge 42 is always the same as the others. This structure ensures that the legs 33, 40 and 41 assume the same position at all times, and therefore can form a stable support structure when fully unfurled, as shown in the figures. It also means all the legs 33, 40 and 41 can be opened out by moving just one of them.

FIGS. 5-8 also illustrate the platform 12 above the burner 11 for supporting an item to be heated (not shown). Referring to FIG. 8, above the primary heat sink structure 20 there is a burner enclosure member 50, which comprises an annular disc 51 with an upwardly extending peripheral flange 52. The burner 11 is disposed in the area defined by the flange 52. Three identical wing members 53 are mounted to the flange 52 by hinges 54. The wing members 53 are moveable on the hinges 54 between a collapsed position, as shown in FIGS. 1 and 7, in which they are axially aligned with the central body 10 and the primary heat sink structure 20, and an unfurled position, as shown in FIGS. 5, 6 and 8, in which they are arranged at an angle to the central body 10 and the primary heat sink structure 20. As shown in FIG. 7, in the collapsed position the sides 55 of the wing members 53 contact one another, so an enclosure 56 is provided around the burner 11. As best shown in FIG. 5, in the unfurled position the top curved surfaces 57 of the wing members 53 pass through the same plane D-D, to create the platform 12.

Mounted around the outside of the flange 52 is a ring 58, which is movable on the flange 52 between an upper position, as shown in FIGS. 1 and 7, in which an upper section 59 thereof overlies the wing members 53 and retains them in the collapsed position, and a lower position, as shown in FIGS. 5, 6 and 8, in which it has been axially displaced from the upper position a sufficient distance to allow the wing members 53 to rotate on the hinges 54 to the necessary angle for the planar platform 12 to be formed by the top surface 57.

Therefore, to move the wing members 53 from the collapsed to the unfurled position the ring 58 is manually moved from its upper to its lower position. To move the wing members 53 in the opposition direction the ring 58 is manually moved from its lower position to its upper position.

Referring now to FIG. 4, this illustrates releasable mounting, generally designated 60, which is provided to retain the butane canister 3 inside the central body 10. The mounting 60 comprises cylindrical frame 61, to which is mounted four lock arms 62, fluid inlet passageway housing 63, inside which pressure valve 64 is disposed (visible in FIG. 1), and main coil spring 65. The four lock arms 62 are each pivotally mounted at an upper end 66 thereof to a downwardly depending section (not visible) of the cylindrical frame 61. The four lock arms 62 are arranged in two pairs of opposed arms, and in each case the two lock arms 62 of each pair are connected at their upper ends 66 by a coil spring 67, which biases the two lock arms 62 laterally towards one another. The lower ends of the lock arms 62 comprise latches 68 with tapered upper surfaces 69.

Referring to FIG. 1, the fluid inlet passageway housing 63 comprises a throat section 70, in which the pressure valve 64 is axially movably mounted. The pressure valve 64 comprises an aperture 71 through which butane vapour can pass in use. Referring back to FIG. 4, the fluid inlet passageway housing 63 comprises four equally circumferentially spaced slots 72, and the pressure valve 64 comprises four equally circumferentially spaced tabs 73 which extend through said slots 72. The tabs 73 are formed into two pairs 74 and 75, and in each case the tabs 73 of each pair 74, 75 extend from opposite sides of the pressure valve 64. Arranged beneath both tabs 73 of the first pair 74 on each side of the fluid inlet passageway housing 63 is articulated linkage 76. This comprises a pair of struts 77 which are pivotally mounted to each other at one end by central pivot 78, and which are pivotally mounted to one of the lock arms 62 at the other end by outer pivot 79. Arranged beneath both tabs 73 of the second pair 75 is main coil spring 65.

The butane canister 3 comprise a retention collar 80, which interacts with the lock arms 62 and the main coil spring 65. The retention collar 80 comprises a tapered outer rim 81.

To retain the butane canister 3 in the releasable mounting 60 it is introduced into the central body 10, until the tapered outer rim 81 of the retention collar 80 comes into contact with the latches 68 of the lock arms 62. Upward movement of the retention collar 80 forces the latch 68 of each lock arm 62 laterally away from the other in the pair, against the force of the coil spring 67. In this configuration the lock arms 62 are in a release position. This occurs until the retention collar 80 moves axially past the latches 68, and the lock arms 62 are then biased towards one another by the coil spring 67, thereby retaining the retention collar 80, as shown in FIGS. 1 and 4. In this configuration the lock arms 62 are in a lock position. In this position the aperture 7 of the butane canister 3 mates with a downwardly depending boss 82 of the fluid inlet passageway housing 63, in a manner in which a fluid seal is created. As such, the compressed butane in the canister 3 can flood the fluid inlet passageway housing 63, up to the release valve 8.

At the same time as this action occurs, the retention collar 80 is introduced to the main coil spring 65, and is pushed against it. When the lock arms 62 retain the retention collar 80 the main coil spring 65 forces the retention collar 80 into contact with the latches 68, which ensures a stable connection. The expansion force of the main spring 65 is not sufficient in isolation to force the retention collar 80 from the releasable mounting 60, partly because it is balanced by the two coil springs 67 biasing the pairs of lock arms 62 towards one another.

To manually remove the butane canister 3 from the releasable mounting 60, it is pulled outward from the central body 10. Application of such a force has the effect that the retention collar 80 rides over the tapered upper surfaces 69, which moves the lock arms 62 laterally away from the other in the pair against the force of the coil spring 67. It will be appreciated that the force of the main coil spring 65 is in the same direction, so the manual force necessary to achieve this action is only that which is required in addition to the expansion force of the main spring 65 acting on the retention collar 80.

The pressure valve 64 is moveable between a first position as shown in FIGS. 1 and 4, in which the tabs 73 are at the top of the slots 72, and a second position which is axially downstream of the first, in which the tabs 73 are at the bottom of the slots 72. As is clear from FIG. 4, when the pressure valve 64 is in the first position, the struts 77 of the articulated linkage 76 are angled in relation to one another about the central pivot 78, so the outer pivots 79 are spaced apart from one another by a distance which allows the lock arms 62 to assume their lock positions. The struts 77 of the articulated linkage 76 are prevented from assuming a smaller angle in relation to one another by the first pair 74 of tabs 73.

The pressure valve 64 is moved between the first and second positions by the pressures on either side of it. In normal use there is a greater pressure on the underside of the pressure valve 64, as the compressed butane is released from the canister 3 and travels through the aperture 71. In addition, it will be appreciated that the main coil spring 65 is mounted in compression between the retention collar 80 and the second pair 75 of tabs 73. Therefore, the main coil spring 65 also forces the pressure valve 64 to assume its first position.

However, if the butane canister 3 overheats then the pressure inside rises and butane is released at a greater flow rate. This increases the pressure in fluid inlet passageway housing 63 and the burner component 14 downstream of the aperture 7. When this happens the pressure on the top side of the pressure valve 64 begins to exceed the pressure on the underside thereof. When the pressure differential exceeds that exerted by the main coil spring 65 acting on the second pair 75 of tabs 73, the pressure valve 64 moves into its second position. This has the effect that the first pair 74 of tabs 73 moves downwards, which forces the struts 77 of the articulated linkage 76 to rotate about the central pivot 78 and assume a greater angle in relation to one another. This moves the outer pivots 79 further apart, which moves the lock arms 62 into their release positions. At the same time, the second pair 75 of tabs 73 is also moved downwards, which further compresses the main coil spring 65. This has the effect of dampening the movement of the pressure valve 64 from its first position to its second.

As soon as the latches 68 of the lock arms 62 are moved into their release positions the butane canister 3 is no longer held in the releasable mounting 60, and the main coil spring 65, which has been compressed even further by the downward movement of the second pair 75 of tabs 73, acts on the retention collar 80 and the butane canister 3 is ejected with some force from the main body 10. Therefore, if the temperature of the butane canister 3 reaches a dangerous level, it will be automatically ejected from the stove 1. This will interrupt the burning process, and the source of heat will cease. The aperture 7 can be of the type which shuts automatically when a probe like the boss 82 is removed therefrom. This prevents the escape of butane when the canister 3 is ejected.

Referring to FIG. 6, it can be seen that a plane E-E of outer ends 83 of the legs 33, 40 and 41 when in the unfurled position is spaced from a plane F-F of a bottom 84 of the butane canister 3. As such a gap 85 is provided under the butane canister 3 when the stove 1 stands in use. This means that if the butane canister 3 is ejected as described above, there is space for it to move downwards. Were this not the case and the butane canister 3 rested on the ground, the stove 1 may be forced upwards by the main coil spring 65 should the pressure valve 64 be moved into its section position.

The TEG 2 is electrically connected to the rechargeable battery 34 by wiring (not visible), and electrical charge generated by the TEG 2 in use is stored in the rechargeable battery 34. The rechargeable battery 34 is a known construction which is capable of storing an electrical charge, but also of delivering a charge via a USB port 86 to a connected chargeable device (not shown). It is also connected to the fan 30 by wiring (not visible), and powers it in use. As the battery enclosure 32 is provided on leg 33, the USB port 86 is readily accessible, and is also sufficiently spaced from the burner 11 to be safely accessed when the stove 1 is operating.

Therefore, in use the stove 1 operates as follows. For storage and transportation the legs 33, 40 and 41 are arranged in the collapsed position, as shown in FIGS. 1 and 7. In addition, the ring 58 is in its upper position so the wing members 53 are also in their collapsed position. As such, the stove 1 assumes a compact and neat shape.

To place a butane canister 3 inside the stove, it is introduced to the central body 10 and mounted in the releasable mounting 60 in the manner described above. The stove 1 can be stored and transported with a butane canister 3 mounted inside it or not.

To use the stove 1 to heat an item it is first placed in its use configuration. The legs 33, 40 and 41 are moved into their unfurled position, either by direct manual manipulation, or by moving the ring 43. The stove 1 can then be placed on a level surface in the manner of a tripod. In addition, the ring 58 is moved to its lower position, allowing the wing members 53 to move to their unfurled positions and form the platform 12, on which the item to be heated can be placed.

To heat the item the control knob 13 is rotated to open the release valve 8 to the desired position. The compressed butane stored in the canister 3 then expands into a gas and floods the fluid pipe 15 and the burner 11, then escapes from the outer ring of gas outlets 36 and the inner ring of gas outlets 37. The user can then ignite the butane using a suitable mechanism, and it will burn from the burner 11 and heat the item on the platform 12.

The release of the compressed butane from the canister 3 causes a thermal reaction which cools the canister 3. However, this cooling effect is prevented from having an adverse effect on the process of atomising the butane, because some of the heat generated by burning the butane in the burner 11 is directed to the canister 3. In particular, heat given off by the outer ring of gas outlets 36 and the inner ring of gas outlets 37 which is generally lateral to the heating axis C-C is absorbed by the annular body 35 of the burner component 14. This is achieved because the outer ring of gas outlets 36 is recessed in the first annular trough 38, and the inner ring of gas outlets 37 is recessed in the second annular trough 39. Further, it is also achieved because the inner ring of gas outlets 37 is itself recessed in relation to the outer ring of gas outlets 36. This captured heat is transferred to the thermal conductor 16, and the planar part 18 in particular, which is in contact with the hot surface 4 of the TEG 2. This heat energy passes through the TEG 2 and is transferred to the heat sink 9, where it is balanced with the cooling effect generated by the canister 3. The balance which is achieved maintains the canister 3 at a temperature of greater than 10 degrees centigrade when the stove is used in a common atmospheric temperature range.

If the thermometer (not visible) inside the tubular housing 24 detects that the temperature of the butane canister 3 drops below 10 degrees centigrade, the electronic circuit on the PCB (not visible) operates the fan 30 in the first direction A, using power stored in the rechargeable battery 34. This draws air over the primary heat sink structure 20 and directs it to the canister 3. This increases the amount of captured heat which is directed to the canister 3, and prevents it from dropping to a temperature at which the atomising process is adversely effected. The temperature of the butane canister 3 will attempt to drop to below 10 degree centigrade if the stove 1 is operated in colder atmospheric conditions, which are either themselves below 10 degrees centigrade, or are not sufficiently higher than that to prevent the canister 3 from dropping to below 10 degrees centigrade as a result of the atomising process.

There is obviously a temperature below which the stove 1 will fail to prevent the butane canister 3 from dropping to a temperature at which the butane will fail to atomise, but it has been found that stove 1 can be operated in temperatures which are significantly below those at which a conventional butane stove can operate. This is a result of both the static heat transfer configuration, as well as the supplementary heat transfer provided by the fan if required.

If the thermometer (not visible) inside the tubular housing 24 detects that the temperature of the butane canister 3 rises above 35 degrees centigrade, the electronic circuit on the PCB (not visible) operates the fan 30 in the second direction B, using power stored in the rechargeable battery 34. This draws air over the canister 3 through the air passageway 31, and directs it to the primary heat sink structure 20. This helps to reduce the temperature of the canister 3 in two ways, firstly it cools it directly by subjecting it to moving air drawn from outside the stove 1, and secondly it increases its ability to impart heat to the heat sink 9 by lowering the temperature of the primary heat sink structure 20. These actions allow the canister 3 to drop back to a lower temperature.

Once the electronic circuit operates the fan 30 in the first direction A, it will operate the fan 30 until the thermometer detects a temperature of the butane canister 3 of 20 degrees, and once it operates the fan 30 in the second direction B, it will operate it until the thermometer detects that the butane canister 3 is at 25 degrees.

In the event that the operation of the fan in the second direction B is insufficient to prevent the heat of the canister 3 reaching dangerous levels at which it may explode, the releasable mounting 60 will eject the canister, in the manner explained in detail above. This function ensures that the stove 1 will always remain safe, despite the apparent dangers of continually directing heat to a canister of compressed butane.

Whenever the burner 11 of the stove 1 is operated as described above, the TEG 2 functions to charge the rechargeable battery 34. In stove 1 the temperature differential achieved between the hot surface 4 and the cold surface 5 of the TEG 2 is approximately 400 degrees centigrade. This will obviously vary according to atmospheric conditions, as well as the condition of the canister 3. If the fan 30 is operated in either the first direction A or the second direction B this will have an effect on the temperature of both the hot surface 4 and the cold surface 5, as well as on the temperature differential across the TEG 2. This may increase the efficiency of the TEG 2, for example if the efficiency of the heat sink 9 is increased by running the fan in direction A with little or no appreciable effect on the hot surface 5. Alternatively, it may decrease the efficiency of the TEG 2, for example if the efficiency of the heat sink 9 is decreased, and the temperature of the hot surface 5 also decreased, by running the fan in direction B. It will be appreciated that there are many variables which may affect the performance of the TEG 2 in practice.

However, despite the above described variables, it has been found that the TEG 2 in stove 1 functions very effectively to charge the battery 34, and significantly better than in known constructions.

Once the rechargeable battery 34 contains an electrical charge, a portable electric item (not shown) can be connected to the USB port 86 via a suitable cable (not shown). The rechargeable battery 34 will provide an electric charge to operate and/or charge the connected item. It has been found that stove 1 can provide sufficient electrical charge to readily operate and/or charge a mobile telephone or the like after a short butane burning time.

The amount of heat given to the item to be heated can be controlled by rotating the control knob 13 to position the release valve 8 at the desired degree of openness. To shut the stove 1 down the control knob 13 is rotated to shut the release valve 8, which cuts off the supply of butane to the burner 11. The TEG 2 will continue to provide an electrical charge to the rechargeable battery 34 until the temperature differential across it drops to a non-functional level, which may be some time after the stove 1 has been switched off.

If the butane canister 3 expires it can be replaced with another. The canister 3 can be manually removed from the central body 10 in the manner explained in detail above, and a replacement inserted.

Once the stove 1 is to be transported or stored once again, the legs 33, 40 and 41 are manually returned to their collapsed positions, either by direct manipulation, or by moving the ring 43. Further, the wing members 53 can also be returned to their collapsed positions, by moving the ring 58 to its upper position.

FIGS. 9 to 12 show a second electricity generation device, in the form of portable camping stove 90, which is similar in construction and operation to portable camping stove 1 described above, except it has a number of further design features. Stove 90 is an evolution of stove 1, and it addresses a number of issues associated with stove 1 which were found during testing.

In particular, an issue which can arise with stove 1 is that the heat sink 9 can be too efficient in transferring heat to the butane canister 3, leading to overheating of the canister 3, and excess switching operation of the fan 30 to reduce the temperature of the canister 3.

In order to address this issue in stove 90 the structural arrangement of the TEG 91 and the heat sink 92 have been changed, and a new mode of operation of the fan 93 has been added.

Firstly, in portable camping stove 90, TEG 91 is arranged laterally under the burner 94. As such, it is interposed between the burner 94 and primary heat sink structure 95, with the hot surface 96 facing upwards towards the burner 94, and the cold surface 97 facing downwards in direct contact with a top surface 98 of the primary heat sink structure 95. With this arrangement the heat passed through the TEG 91 is more efficiently dissipated to atmosphere via the cooling fins 99 of the primary heat sink structure 95.

Secondly, in stove 90 the heat sink 92 does not surround the canister 100 so tightly as in stove 1. In particular, two axially extending air channels 101 are formed in the heat sink 92 in order to reduce the degree to which the canister 100 is thermally connected by radiation to the heat sink 92 by increasing the volume of air between the canister 100 and the heat sink 92. The air channels 101 also increase the efficiency of the fan 93, as explained further below.

Referring to FIG. 9, a central body 102 of the stove 90 comprises three axially aligned chassis sections. A first chassis section 103 houses the primary heat sink structure 95, a second chassis section 104 houses the fan 93 and the release valve 105, and a third chassis section 106 houses the canister 100. All three chassis sections 103, 104 and 106 form a part of the heat sink 92, with the third chassis section 106 being the equivalent of the tubular housing 24 in stove 1.

Referring to FIG. 11, the third chassis section 106 of the central body 102 comprises three first circumferential sections 107 which are a first radius from a central axis 108 of stove 90, and two second circumferential sections 109 which are a greater second radius from the central axis 108. The three first circumferential sections 107 are dispersed at regular 120 degree intervals around the circumference of the third chassis section 106, and they coincide with the circumferential position of the three legs 110, as is clear from FIG. 12. The two second circumferential sections 109 are arranged at 120 degrees to one another, and also each at 120 degrees to the location of rechargeable battery 111, which is mounted to the third chassis section 106 of the central body 102. The positioning of the rechargeable battery 111 at this location prevents the possibility of having a third second circumferential section there.

The two second circumferential sections 109 facilitate the provision of the two air channels 101.

Therefore, a smaller area of the third chassis section 106 is in close proximity to the canister 100 in stove 90, than the area of the tubular housing 24 which is in close proximity to the canister 3 in stove 1. The surface area of the two second circumferential sections 109 is spaced apart from the exterior surface 112 of the canister 100. With this arrangement less heat from the TEG 91 is transferred to the canister 100, and less of the cooling effect generated by the canister 100 in use is transferred to the heat sink 92. As a result the canister 100 remains cooler in use than canister 3 in stove 1.

Turning to the fan 93, in stove 90 the fan 93 operates in the first direction A only, and it operates continuously when the stove 90 is in use, rather than according to a detected temperature of the canister 3 as in stove 1. As such, the fan 93 in stove 90 only serves to direct heat from the burner 94 towards the canister 100 in order to increase its temperature. The fan 93 is controlled by an electronic circuit provided on a PCB (not visible), which is housed alongside the rechargeable battery 111. When the release valve 105 is opened the electronic circuit operates the fan 93 with power from the rechargeable battery 111, and when the release valve 105 is closed, the electronic circuit ceases operation of the fan 93.

In order to control the effectiveness of the fan 93 in radiating heat towards the canister 100, a selectively open and closable grill 112 is provided between the release valve 105 and the canister 100, as best seen in FIG. 10. The grill 112 comprises an upper static part 113 which comprises a plurality of circumferentially spaced apertures 114, and a lower rotatable part 115 which comprises a plurality of corresponding circumferentially spaced apertures 116. The lower rotatable part 115 is rotatable from a first position, as shown in FIG. 10 in which the apertures 116 are aligned with the apertures 114, thereby opening them, to a second position in which the apertures 116 are partially displaced from the apertures 114, thereby partially closing them, and then on to a third position in which the apertures 116 are fully displaced from the apertures 114, thereby fully closing them. The lower rotatable part 115 is manually movable between the first, second and third positions via lateral movement of operating trigger 117.

Therefore, manual lateral placement of the operating trigger 117 adjusts the amount of heat which is radiated from the fan 93 to the canister 100, by increasing or decreasing the air flow. The capacity of the fan 93, and the arrangement of the grill 112 have been configured so the stove 90 has three modes of operation, which are to be used according to the ambient temperature. The first, in which the apertures 114 are open, and therefore the greatest amount of air flow is permitted, is a Cold setting to be used when the ambient temperature is about −3 to 5 degrees centigrade. In that ambient temperature range the heat sink 92 does not transfer enough heat to the canister 100 to keep it within the temperature range in which the butane atomises efficiently into a burnable gas. However, the maximum flow of hot air from the fan 93 through the grill 112 is sufficient to keep the canister 100 within this temperature range.

The second mode of operation, in which the apertures 114 are partially closed, and therefore a medium amount of air flow is permitted, is a Mild setting to be used when the ambient temperature is about 5 to 15 degrees centigrade. In that ambient temperature range the heat sink 92 still does not transfer enough heat to the canister 100 to keep it within the temperature range in which the butane atomises efficiently into a burnable gas, but it brings it closer than if the ambient temperature is less than 5 degrees. However, the partial flow of hot air from the fan 93 through the grill 112 is sufficient additional heat to keep the canister 100 within this temperature range.

The third mode of operation, in which the apertures 114 are fully closed, and therefore no air flow is permitted, is a Hot setting to be used when the ambient temperature is above 15 degrees centigrade. In that ambient temperature range the heat sink 92 transfers sufficient heat to the canister 100 to keep it within the temperature range in which the butane atomises efficiently into a burnable gas. As such no additional heat is required from the fan 93.

Referring to FIG. 12, the operating trigger 117 protrudes through an opening 118 in the second chassis section 104, which defines the movement of the operating trigger 117 between the first and third positions. Markings (not shown) are provided on the exterior 119 of the second chassis section 104 to indicate the position the operating trigger 117 must assume to set the stove to the Cold, Mild and Hot settings.

It will be appreciated that the skilled person can design and set-up the stove 90, and the efficiency of the heat sink 92 and the fan 93 in particular, so the canister 100 is kept within its ideal operating temperature range when the correct Cold, Mild or Hot setting is selected according to the ambient temperature.

Therefore, this single direction controllable mode of operation of the fan 93 works alongside the reduction in the effectiveness of the heat sink 92, to more effectively control the temperature of the canister 100. In effect, the heat sink 92 provides a base amount of heat transfer to the canister 100 which is constant according to the ambient temperature, and which on its own is not sufficient to overheat the canister 100 in any ambient temperature, while the fan 93 provides an adjustable form of additional heat radiation to the canister 100 which can be controlled, and which maintains the canister 100 within its ideal operational temperature range. This is a superior arrangement to in stove 1, in which the heat sink 9 provides a base amount of heat transfer to the canister 3 which is constant according to the ambient temperature, but which can transfer too much heat to the canister 3 and overheat it in some ambient temperatures. The fan 30 is then operated in direction B to counteract this, which is effectively a waste of energy. In stove 90 this is not necessary because the heat sink 92 cannot overheat the canister 100. As such, the fan 93 only needs to operate in the first direction A to heat the canister 100 when needed.

The fan 93 has a second function, which is to assist in cooling the cold surface 97 of the TEG 91. As is clear from FIG. 9, the fan 93 is arranged laterally underneath the primary heat sink structure 95, and in particular underneath the cooling fins 99. Further, the first chassis section 103 which houses the primary heat sink structure 95 comprises a plurality of radially facing apertures 120, best seen in FIG. 12, and the second chassis section 104 which houses the fan 93 at the top, comprises a plurality of radially facing apertures 121. Therefore, when the fan 93 operates in direction A, air is drawn through the apertures 120, into the first chassis section 103 and over the cooling fins 99. The air then passes through the fan 93 into the second chassis section 104. When the stove 90 is arranged in the Hot setting described above, and the apertures 114 of the grill 112 are fully closed, all the air is then blown by the fan 93 out of the apertures 121 in the second chassis section 104. When the stove 90 is arranged in the Mild or Cold settings described above, and the apertures 114 are partially or fully open, some of the air passes through the grill 112 and into the third chassis section 106, and some of the air passes through the apertures 121 in the second chassis section 104.

This continuous drawing in of air from atmosphere over the primary heat sink structure 95 serves to increase the cooling effect provided by the primary heat sink structure 95. This has two effects, firstly, it reduces the effectiveness of the heat sink 92 in transferring heat to the canister 100 which it would otherwise have done given its physical structure, and thus forms a part of the overall operational characteristics of the heat sink 92 which is taken into account when designing and setting up the stove 90 so it works correctly in the Cold, Mild and Hot settings described above. Secondly, it compensates for the reduced physical effectiveness of the heat sink 92 compared to the heat sink 9 in stove 1, which has been designed into stove 90 in order to prevent the canister 100 from overheating, as described above. In effect, the continuous operation of the fan 93 serves to improve the primary function of the heat sink 92, which is to cool the cold surface 97 of the TEG 91, and thereby maintain the greatest temperature differential between the hot surface 96 and the cold surface 97 of the TEG 91, in order to most effectively generate electricity to store in the rechargeable battery 111. In effect, the continuous operation of the fan 93 ensures that the heat sink 92 performs its primary function of cooling the cold surface 97 of the TEG 92 effectively at its upper end, while still allowing the heat sink 92 to be less effective in its secondary function of transferring heat to the canister 100 at its lower end. The heat drawn from the primary cooling structure 95 by the fan 93 is then used selectively to control the temperature of the canister 100 by means of the grill 112.

There are a number of other structural differences between stove 1 and stove 90, which have been made to accommodate the above described arrangements, or to make other improvements. Firstly, as is best seen in FIG. 10, the fluid pipe 122 extending from the release valve 105 extends radially outwardly before extending upwards, in order to avoid the fan 93 and primary heat sink structure 95. It then extends radially inwardly to the burner 94.

The burner 94 also has a different thermal conductor arrangement to burner 14 in stove 1. In particular, as best seen in FIG. 10, three support posts 123 are arranged circumferentially around the burner 94 at 120 degree intervals, which each comprise a radially inwardly extending support tab 124. The three support posts 123 are mounted to a base part 125, which comprises an underside 126 in direct contact with the hot surface 96 of the TEG 91.

The support tabs 124 provide central support for an item to be heated in use (not shown). However, they also extend directly over the rings of gas outlets 127 of the burner 94. Therefore, they are heated by the burner 94 in use, and the heat is transferred down the three support posts 123, into the base part 125, and to the hot surface 96 of the TEG 91. This is a more effectively way to recycle heat emitted by the burner 94 for use in generating electricity than by relying on the heat of the burner component 94 itself as in stove 1.

As best seen in FIG. 12, stove 90 comprises a different arrangement of wing members 128 than stove 1. Namely, mounted on top of the first chassis section 103 is an annular framework 129 comprising three axially extending mounting slots 130 (best seen in FIG. 10), which are arranged at 120 degree intervals to each other, and each at 60 degrees to the support posts 123. Mounted in each mounting slot 130 is an arcuate wing member 128, which can be rotated about the axis of its particular mounting slot 130 between a collapsed position in which it is aligned with the annular framework 129, and an unfurled position, as shown in FIG. 12, in which it extends generally radially outwardly from the central axis 108 of the stove 90. Each wing member 128 comprises a corrugated top surface 131 which is normal to the central axis 108. Collectively the support tabs 124 and the top surfaces 131 of the wing members 128 comprise a support platform 132 for the item to be heated (not shown), which is superior to that in stove 1, as it is greater in surface area, and in radial extent from the central axis 108 of the stove 90. It therefore serves to support the item to be heated (not shown) more effectively and safely.

Finally, the three legs 110 are independently moveable, which allows stove 90 to be used more effectively on uneven ground than stove 1, which has legs 33, 40 and 41 which move in unison with one another. In particular, a top 133 of each leg 110 is mounted to the exterior 119 of the second chassis section 104 by a sliding hinge 134, which is axially aligned with a first circumferential section 107 of the third chassis section 106 below. Each sliding hinge 134 comprises a track 135, in which a sliding hinge body (not visible) can travel. This arrangement allows the top 133 of the corresponding leg 110 to move axially up and down the exterior 119 of the second chassis section 104, as well as allowing the leg 110 to rotate away from the central axis 108 of the stove 90 about the sliding hinge body.

A row of teeth 136 is provided inside each track 135, and the top 133 of each leg 110 comprises a spring loaded pawl (not visible) which can engage the teeth 136 in order to locate the top 133 of the leg 110 at a particular position in the track 135. The spring loaded pawl can be released from engagement with the teeth 136 by depressing trigger 137.

Each leg 110 comprises a support strut 138, an inner end 139 of which is mounted to a static hinge 140 provided on an exterior 141 of the third chassis section 106, and an outer end of which (not visible) is mounted to a static hinge (not visible) on each leg 110.

Therefore, each leg 110 can be moved between a collapsed position in which the sliding hinge 134 is at the top of the track 135 and the leg 110 overlies the central body 102 of the stove 90, and a sequence of unfurled positions in each of which the pawl engages one of the teeth 136. In FIG. 12 the legs 110 are arranged at their most unfurled position, with each sliding hinge 134 at the bottom of its track 135 and the pawl engaging the lowermost of the teeth 136. In this position the bottom 142 of each leg 110 has been forced radially outwardly of the central axis 108 of the stove 90 by the support strut 138, due to the way it is statically mounted to both the third chassis section 106 and the leg 110. It will be appreciated however that each leg 110 can be positioned at any of four less unfurled positions, at which the pawl engages one of the higher teeth 136. To release each leg 110 in order to return it to either a higher unfurled position or the collapsed position, the trigger 137 is depressed to disengage the pawl from the teeth 136 and allow the sliding hinge 134 to move freely in its track 135.

This arrangement is superior to the leg arrangement in stove 1, because stove 90 can be safely and securely mounted on uneven ground, because the bottom 142 of each leg 110 can be positioned individually and securely.

Stove 90 has a different releasable mounting structure 143 of the canister 100 than stove 1, but this is not further described as it is not of particular relevance to the operation of stove 90. It simply engages and disengages the canister 100 in a known way.

In use stove 90 operates in essentially the same way as stove 1 described above. For storage and transportation the legs 110 are arranged in the collapsed position. In addition, the wing members 128 are arranged in the collapsed position. As such stove 90 assumes a compact and neat shape.

To place a butane canister 100 inside stove 90, it is introduced to the third chassis section 106 and mounted to the releasable mounting 143. The stove 90 can be stored and transported with a butane canister 100 mounted inside it or not.

To use stove 90 to heat an item it is first placed in its use configuration. The legs 110 are moved into an appropriate unfurled position as described above, according to the nature of the surface upon which stove 90 is to be used. In addition, the wing members 128 are rotated into their unfurled positions so the support platform 132 is formed.

To heat the item the control knob 144 is rotated to open the release valve 105 to the desired position. The compressed butane stored in the canister 100 then expands into a gas and floods the fluid pipe 122 and the burner 94, then escapes from the rings of gas outlets 127. The user can then ignite the butane using a suitable mechanism, and it will burn from the burner 94 and heat the item on the platform 132. When the control knob 144 is rotated the electronic circuit operates the fan 93 in direction A with power from the rechargeable battery 111, and it continues to do so while the control knob 144 is rotated to a position at which the release valve 105 is open.

Heat from the burner 94 is captured by the support tabs 124, transferred down the three support posts 123 into the base part 125, and to the hot surface 96 of the TEG 91. It then passes through the TEG 91 and out of the cold surface 97 thereof. This heat is then transferred to the heat sink 92, where it travels through the first chassis section 103, the second chassis section 104 and the third chassis section 106. Finally, the heat radiates through the air gap between the third chassis section 106 and the canister 100, which serves to heat the canister 100. Because the surface area of the two second circumferential sections 109 is spaced apart from the exterior surface 112 of the canister 100 less heat from the TEG 91 is transferred to the canister 100 than would otherwise be the case, and less of the cooling effect generated by the canister 100 in use is transferred to the heat sink 92. As a result the canister 100 remains cooler in use than canister 3 in stove 1. The heat transferred from the TEG 91 to the canister 100 is a base amount which is constant according to the ambient temperature, and which on its own is not sufficient to overheat the canister 100 in any ambient temperature.

The release of the compressed butane from the canister 100 causes a thermal reaction which cools the canister 100. To ensure that the canister 100 remains within the temperature range at which the butane atomises effectively into a burnable gas, the user selects the Cold, Mild or Hot setting according to the ambient temperature, using the trigger 117. If the ambient temperature is between −3 and 5 degrees centigrade the heat sink 92 does not transfer enough heat to the canister 100 to keep it within the temperature range in which the butane atomises efficiently into a burnable gas. Therefore, the user selects the Cold setting, which positions the lower rotatable part 115 of the grill 112 so the apertures 116 are aligned with the apertures 114 of the upper static part 113, thereby opening them. Air is drawn from atmosphere by the fan 93 through the apertures 120, into the first chassis section 103 and over the cooling fins 99, thereby heating it. The air then passes through the fan 93 into the second chassis section 104, where some of it exits the stove 90 through the apertures 121 in the second chassis section 104, but most of it passes through the grill 112 into the third chassis section 106. It then travels down the two axially extending air channels 101, as well as the space between the three first circumferential sections 107 and the canister 100, which effectively heats the canister 100 because a sufficient volume of air passes over the canister 100. Therefore, in the Cold setting the maximum amount of hot air delivered by the continuous operation of the fan 93 is directed to the canister 100. This is sufficient additional heat to keep the canister 100 within its operational temperature range.

If the ambient temperature is about 5 to 15 degrees centigrade the heat sink 92 still does not transfer enough heat to the canister 100 to keep it within the temperature range in which the butane atomises efficiently into a burnable gas. Therefore, the user selects the Mild setting, which positions the lower rotatable part 115 of the grill 112 so the apertures 116 are partially aligned with the apertures 114, thereby only partially opening them. As such, more of the air passing through the fan 93 exits the second chassis section 106 through the apertures 121, and less passes through the grill 112 into the third chassis section 106. This lesser amount of hot air is about right to maintain the canister 100 within its operational temperature range at those ambient temperatures.

If the ambient temperature is above 15 degrees centigrade the heat sink 92 transfers enough heat to the canister 100 to keep it within the temperature range in which the butane atomises efficiently into a burnable gas. In practice, at ambient temperatures above about 15 degrees the canister 100 actually requires no additional heating to remain in its operational temperature range. However, as referred to above, the heat transferred to the canister 100 by the heat sink 92 at these ambient temperatures is not enough to overheat the canister 100, so the provision of such heat in use is not a problem. Therefore, the user selects the Hot setting, which positions the lower rotatable part 115 of the grill 112 so the apertures 116 are displaced from the apertures 114, thereby fully closing them. As such, all the air passing over the fan 93 exits the second chassis section 106 through the apertures 121, and non passes through the grill into the third chassis section 106.

It will be appreciated that the amount of heat generated by the burner 94 will depend on the degree to which the outlet valve 105 is opened. The above description assumes that the burner 94 is operated to its maximum capacity. If not, and less heat is generated by the burner 94 because it burns less butane, then the heat sink 92 will not transfer as much heat to the canister 100 as otherwise. However, in these circumstances the stove 90 will still function generally as described above. If not, and the butane fails to atomise into a burnable gas, the user can switch from the Hot to Mild, or from Mild to Cold settings, if possible, to direct more heat to the canister 100 from the fan 93.

Whenever the burner 94 is operated as described above, the TEG 91 functions to charge the rechargeable battery 111. In stove 90 the temperature differential achieved between the hot surface 96 and the cold surface 97 of the TEG 91 is approximately 400 degrees centigrade. This will obviously vary according to atmospheric conditions, as well as the condition of the canister 100. The fan 93 operates continuously in direction A to maximise the efficiency of the heat sink 92 by drawing air from atmosphere over the cooling fins 99. This cooling effect is the same regardless of which of the Cold, Mild or Hot settings the stove 90 is in. This arrangement is an improvement over stove 1, in which the fan 30 only operates in direction A some of the time, and which operates to reduce the effectiveness of the TEG 2 by operating in direction B some of the time.

Once the rechargeable battery 111 contains sufficient electrical charge, a portable electric item (not shown) can be connected to either of the outlet ports 145 or 146. The rechargeable battery 111 will provide an electric charge to operate and/or charge the connected item.

The amount of heat given to the item to be heated can be controlled by rotating the control knob 144 to position the release valve 105 at the desired degree of openness. To shut the stove 90 down the control knob 144 is rotated to shut the release valve 105, which cuts off the supply of butane to the burner 94, and also switches off the fan 93. The TEG 91 will continue to provide an electrical charge to the rechargeable battery 111 until the temperature differential across it drops to a non-functional level, which may be some time after the stove 90 has been switched off.

Once the stove 90 is to be transported or stored once again, the legs 110 are manually returned to their collapsed positions, and the wing members 128 can also be returned to their collapsed positions.

The present invention can be embodied in other ways without departing from the scope of claim 1. In particular, in alternative embodiments (not shown) the invention is used in industrial settings involving the release of compressed fluid from a canister, where the cooling effect would otherwise be wasted. In one particular alternative (not shown) the industrial arrangement is such that the compressed fluid atomises into a gas in pipework downstream of the tank, and as such the exterior surface to which the heat sink is thermally connected is this pipework, and not the tank itself. As such, the container in this version comprises the tank and the pipework down which the fluid travels.

In other alternative embodiments (not shown) the invention is used in industrial settings involving the use of a TEG, and a canister of compressed fluid is added to provide a cooling effect to the cold surface, thereby to increase the temperature differential across the TEG, and therefore is operating efficiency.

It will also be appreciated that many of the features of the stove 1 can be altered without departing from the scope of claim 1. For example, on one alternative embodiment (not shown) four legs are provided rather than three. In another alternative embodiment (not shown) no pressure release valve is provided.

In another alternative embodiment (not shown) the air passageway between the butane canister and the tubular sleeve is minimised, so a direct contact area between the exterior surface and the tubular sleeve is as large as possible. This will improve the efficiency of the thermal transfer in that area, and my be required to maximise the efficiency of the device. The air passageway in such a construction can be one or more troughs formed in the surface of the tubular sleeve.

Therefore, the present invention addresses the two main problems with the prior art. Firstly, waste heat from a stove burner is used in a controlled manner to prevent the temperature of the butane canister powering it from dropping too low. As such, a butane powered stove can be used in far lower ambient temperatures than currently. Secondly, that waste heat is combined with the cooling effect generated by releasing the compressed fluid from the canister to operate a TEG at a very high efficiency, and provide a highly practicable outdoor power supply. In addition to this, the invention also provides a neat and compact portable camping stove with various collapsible features, and it also provides a new canister ejection mechanism to improve safety.

1. An electricity generation device comprising a thermoelectric generator and a container of compressed fluid, in which said thermoelectric generator comprises a hot surface and a cold surface, in which said container comprises an exterior surface and an aperture, in which said device comprises a release valve for opening said aperture to release said compressed fluid, in which expansion of said compressed fluid cools said exterior surface, and in which a heat sink extends from said cold surface to at least part of said exterior surface.

2. An electricity generation device as claimed in claim 1 in which said device further comprises a burner, in which said release valve is fluidly connected to said burner, in which said compressed fluid is combustible and when expanded comprises a fuel for said burner, in which combustion of said expanded fluid heats said burner, and in which a thermal conductor extends from said burner to said hot surface.

3. An electricity generation device as claimed in claim 2 in which an air gap is provided between a section of said heat sink and at least part of said exterior surface, in which said device further comprises a fan disposed in said air gap, in which said fan is operable in a first direction to radiate heat from said heat sink to said container, and in a second direction to radiate heat from said container to said heat sink, in which said device further comprises a thermometer to detect the temperature of said container and a control means operatively connected to said fan, in which said control means operates said fan in said first direction when said thermometer detects a temperature of said container below a first pre-determined threshold, and in which said control means operates said fan in said second direction when said thermometer detects a temperature of said container above a second pre-determined threshold.

4. An electricity generation device as claimed in any of claim 3 in which said burner comprises an heating axis and radiates heat in use in a first direction along said heating axis, in which said burner comprises an annular body comprising an outer ring of gas outlets and an inner ring of gas outlets disposed radially inside said outer ring, in which said inner ring is axially positioned below said outer ring on said heating axis, and in which said annular body comprises a first annular trough at a base of which said outer ring is disposed, and a second annular trough at a base of which said inner ring is disposed.

5. An electricity generation device as claimed in claim 4 in which said release valve is fluidly connected to said burner by a fluid pipe, in which said thermal conductor comprises a tubular part which defines said fluid pipe, and a planar part extending from said tubular part which contacts said hot surface, in which said heat sink comprises a primary heat sink structure in thermal connection with said cold surface and comprising a plurality of cooling fins, in which said fluid pipe comprises an axis, in which said primary heat sink structure is annular, and in which said plurality of cooling fins extend radially outwardly from said axis.

6. An electricity generation device as claimed in claim 5 in which said primary heat sink structure comprises an underside, in which said heat sink further comprises a tubular housing which surrounds at least part of said container, in which a first end of said tubular housing comprises a radially extending flange which is in thermal connection with said underside, in which said air gap extends between said underside and a top side of said container, and in which said fan is mounted to said underside in a position which is axially aligned with said thermoelectric generator.

7. An electricity generation device as claimed in claim 6 in which an air passageway is provided between said container and said tubular housing, through which said fan can draw air when it is operated in said second direction.

8. An electricity generation device as claimed in claim 1 in which said device is a portable stove comprising a central body for retaining said container, a burner for burning the expanded fluid from said container, a platform above said burner for supporting an item to be heated, and a manually operable control knob for opening and closing said release valve.

9. An electricity generation device as claimed in claim 8 in which said central body comprise a plurality of legs on which said portable stove is standable in use, in which each of said plurality of legs is mounted to said central body by a first hinge, and is moveable between a collapsed position in which it overlies said central body and an unfurled position in which it extends away from said body at an angle.

10. An electricity generation device as claimed in claim 1 in which said device further comprises a rechargeable battery for storing electrical charge generated by the thermoelectric generator in use.

11. An electricity generation device as claimed in claim 10 in which said container comprises a retention collar, in which said device comprises a releasable mounting for retaining said container in said central body, in which said releasable mounting comprising a plurality of lock arms, each of which is movable between a lock position in which it retains said retention collar, and a release position in which it allows movement of said retention collar in and out of said releasable mounting, in which each of said plurality of lock arms is biased into its lock position by a first spring, in which said container is biased away from said releasable mounting by a second spring, in which said device comprises a fluid inlet passageway to which said container is fluidly connected, in which said fluid inlet passageway comprises a pressure valve, in which a linkage connects said pressure valve to said plurality of lock arms, in which said pressure valve is movable between a first position in which said linkage allows said plurality of lock arms to assume said lock position, and a second position in which said linkage moves said lock arms into said release position, in which said pressure valve is biased into said first position by a third spring, in which said pressure valve is configured to move into said second position when a pre-determined back pressure is present in said fluid inlet passageway, in which said central body comprise a plurality of legs on which said portable stove is standable in use, and in which a plane of outer ends of said plurality of legs is spaced from a plane of a bottom of said container, such that a gap is provided under said container when said portable stove stands in use.

12. An electricity generation device as claimed in claim 1 in which an air gap is provided between a section of said heat sink and at least part of said exterior surface, in which said device further comprises a fan disposed in said air gap, in which said fan is operable to radiate heat from said heat sink to said container.

13. An electricity generation device as claimed in claim 12 in which said fan is operated continuously when said release valve is open.

14. An electricity generation device as claimed in claim 13 in which a selectively open and closable grill comprising a plurality of open and closable apertures is provided between said section of said heat sink and said part of said exterior surface, which grill is movable between a first position in which said apertures are open, a second position in which said apertures are partially open, and a third position in which said apertures are closed.

15. An electricity generation device as claimed in claim 14 in which said device is a portable stove comprising a central body for retaining said container, a burner for burning the expanded fluid from said container, a platform above said burner for supporting an item to be heated, and a manually operable control knob for opening and closing said release valve, in which in the vicinity of said container said central body comprises a plurality of first circumferential sections which are a first radius from a central axis of the portable stove, and a plurality of second circumferential sections which are a greater second radius from said central axis.

16. An electricity generation device as claimed in claim 12 in which said device further comprises a burner, in which said release valve is fluidly connected to said burner, in which said compressed fluid is combustible and when expanded comprises a fuel for said burner, in which combustion of said expanded fluid heats said burner, and in which a thermal conductor extends from a point above said burner to said hot surface.
